(19) United States
(12) Patent Application Publication
(10) Pub. No.: US 2024/0186164 A1
(43) Pub. Date: Jun. 6, 2024

(54) WAFER HOLDER AND METHOD FOR OPERATING THE SAME

(71) Applicant: INNOSCIENCE (SUZHOU) SEMICONDUCTOR CO., LTD., Suzhou City (CN)

(72) Inventor: Xudong ZHU, Suzhou City (CN)

(21) Appl. No.: 17/799,267

(22) PCT Filed: Jul. 15, 2022
(86) PCT No.: PCT/CN2022/106059

§ 371 Date: Aug. 12, 2022

(51) Int. Cl. H01L 21/673

(52) U.S. Cl. CPC H01L 21/67303

(57) ABSTRACT

A wafer holder including a carrier plate, blocking devices, fasteners, and a cover plate is provided. The carrier plate has a carrier surface. The blocking devices are disposed on the carrier plate. The cover plate is located above the carrier surface of the carrier plate. The blocking devices are disposed around the carrier surface. Each of the blocking devices has a plurality of openings. The fasteners pass through the openings, and the cover plate is fastened on the blocking devices through fasteners.

### FIELD OF THE INVENTION

The present invention generally relates to a nitride-based semiconductor wafer holder. More specifically, the present invention relates to a nitride-based semiconductor wafer holder with a movable cover plate.

### BACKGROUND

In recent years, intense research on high-electron-mobility transistors (HEMTs) has been prevalent, particularly for high power switching and high frequency applications. III-nitride-based HEMTs utilize a heterojunction interface between two materials with different bandgaps to form a quantum well-like structure, which accommodates a two-dimensional electron gas (2DEG) region, satisfying demands of high power/frequency devices. In addition to HEMTs, examples of devices having heterostructures further include heterojunction bipolar transistors (HBT), heterojunction field effect transistor (HFET), and modulation-doped FETs (MODFET).

In the process of manufacturing semiconductor wafers having HEMTs, the wafers must be transported between processes. The wafers are fragile and damage to the surface of the wafers may cause serious issue. To prevent from damaging the wafers, the wafers must be packaged and transported to minimize harm. During transportation, multiple semiconductor wafers are stacked into a container. A plurality of protecting layers made of resilient material such as sponge are needed. In each container, the protecting layers need to fill-up the space between the wafer and the cover of the container, so that the wafers can hold still in every container. However, lots of protecting layers are needed if the container is carrying less wafers, and it's also a waste of protection layers and time.

### SUMMARY OF THE INVENTION

In accordance with one aspect of the present disclosure, a wafer holder is provided. The wafer holder includes a carrier plate, blocking devices, fasteners, and a cover plate. The carrier plate has a carrier surface. The blocking devices are disposed on the carrier plate. The cover plate is located above the carrier surface of the carrier plate. The blocking devices are disposed around the carrier surface. Each of the blocking devices has a plurality of openings. The fasteners pass through the openings, and the cover plate is fastened on the blocking devices through fasteners.

In accordance with one aspect of the present disclosure, operating method of a wafer holder is provided. The method includes steps as follows. At least one wafer is disposed on a carrier surface of a carrier. A cover plate is disposed on the wafer. A plurality of fasteners are inserted to a plurality of openings of a plurality of blocking devices located around the carrier surface. The cover plate is fastened on the blocking devices. The wafer holder comprises the carrier plate, the blocking devices, and the fasteners. The fasteners pass through the openings, and the cover plate is fastened on the blocking devices through the fasteners.

In accordance with one aspect of the present disclosure, a wafer holder is provided. The wafer holder includes a carrier plate, a plurality of blocking devices, and a cover plate. The carrier plate has a carrier surface. The cover plate is located above the carrier surface. The blocking devices are disposed around the carrier surface. The cover plate is coupled to the blocking devices. The blocking devices are configured to adjust a height of the cover plate.

Based on the above, in embodiments of the present disclosure, the blocking devices can hold the cover plate above the carrier surface, and such a configuration can adjust the height of the cover plate. Moreover, when one or more wafers are disposed on the carrier surface, and the space between the wafers and the cover plate can be fixed by adjusting the height of the cover plate. Hence, the packaging process of the wafers can be more efficient, and fewer protecting layers are needed.

### BRIEF DESCRIPTION OF THE DRAWINGS

Aspects of the present disclosure are readily understood from the following detailed description when read with the accompanying figures. It should be noted that various features may not be drawn to scale. That is, the dimensions of the various features may be arbitrarily increased or reduced for clarity of discussion. Embodiments of the present disclosure are described in more detail hereinafter with reference to the drawings, in which:

FIG. 1 is a top view of a carrier plate of a wafer holder according to some embodiments of the present disclosure;

FIG. 2 is an exploded view of a carrier plate and a cover plate of a wafer holder according to some embodiments of the present disclosure;

FIG. 3 is a perspective view of a wafer holder according to some embodiments of the present disclosure;

FIGS. 4-6 are sectional views of steps of operating method of the wafer holder according to some embodiments of the present disclosure;

FIG. 7 is a perspective view of a fastener according to some embodiments of the present disclosure;

FIG. 8 is a top view of a cover plate according to some embodiments of the present disclosure;

FIG. 9 is a front view of a blocking device according to some embodiments of the present disclosure;

FIG. 10 is a sectional view of a wafer holder according to some embodiments of the present disclosure;

FIG. 11 is a top view of a carrier plate according to some other embodiments of the present disclosure;

FIG. 12 is a front view of a blocking device according to some embodiments of the present disclosure;

FIG. 13 is a top view of a carrier plate according to some other embodiments of the present disclosure; and

FIG. 14 is a front view of a blocking device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

Spatial descriptions, such as “above,” “on,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

Further, it is noted that the actual shapes of the various structures depicted as approximately rectangular may, in actual device, be curved, have rounded edges, have somewhat uneven thicknesses, etc. due to device fabrication conditions. The straight lines and right angles are used solely for convenience of representation of layers and features.

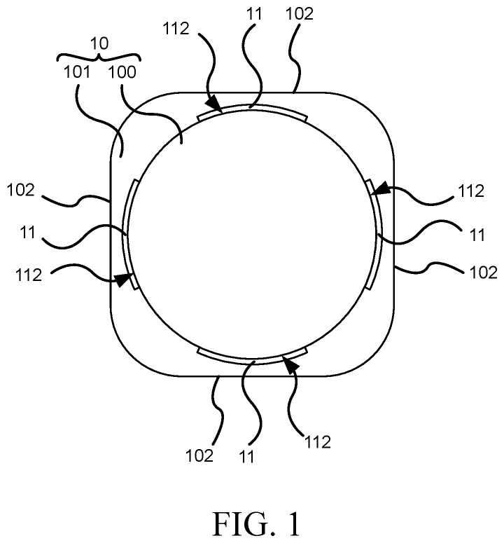

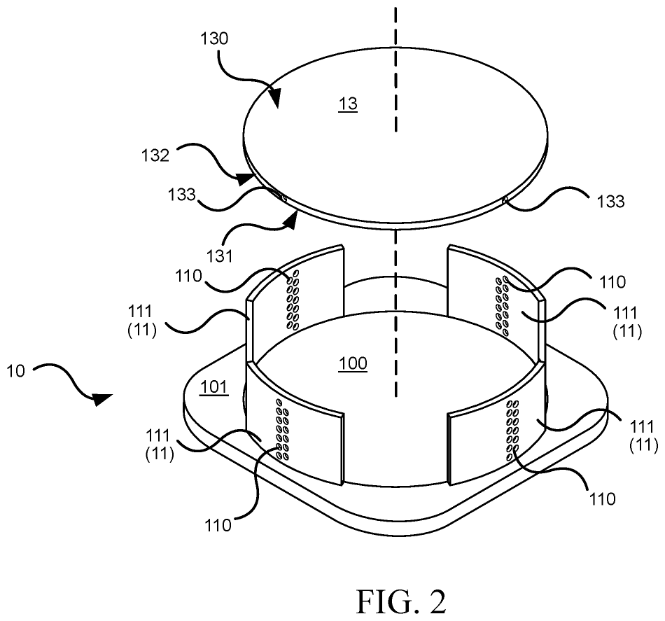

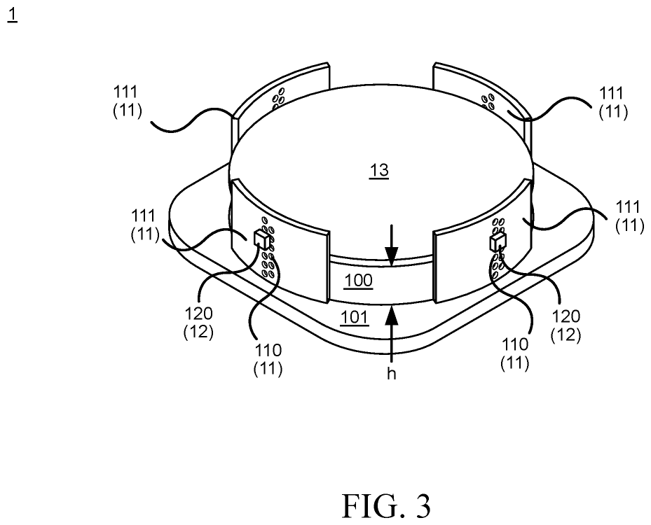

FIG. 1 is a top view of a carrier plate of a wafer holder according to some embodiments of the present disclosure, and FIG. 2 is an exploded view of the carrier plate and a cover plate of the wafer holder according to some embodiments of the present disclosure, and FIG. 3 is a perspective view of the wafer holder according to some embodiments of the present disclosure. A wafer holder 1 includes a carrier plate 10, a plurality of blocking devices 11, a plurality of fasteners 12, and a cover plate 13.

The carrier plate 10 has a carrier surface 100, and the carrier surface 100 is configured to carry one or more nitride-based semiconductor wafers. For example, the nitride-based semiconductor wafer has a GaN layer and a AlGaN layer, and a plurality of HEMT devices are form in the nitride-based semiconductor wafer. The AlGaN layer is disposed on the GaN layer. The bandgap of the AlGaN layer and the bandgap of the GaN layer are different, and a 2DEG region is formed. The carrier surface 100 can only carry nitride-based semiconductor wafers.

The blocking devices 11 are disposed on the carrier plate 10. To be specific, the blocking devices 11 are disposed on the top of the carrier plate 10, and the blocking devices 11 are disposed around the carrier surface 100.

Each of the blocking devices 11 has a plurality of openings 110, and the fasteners 12 pass through the openings 110. In this embodiment, the number of blocking devices 11 and the number of the fasteners 12 are the same, and every fastener 12 is corresponded to a set of the openings 110 on one of the blocking devices 11. In every blocking device 11, one of the openings 110 is passed through by the fastener 12.

The cover plate 13 is located above the carrier surface 100, and the cover plate 13 is fastened on the blocking devices 11 through the fasteners 12.

By fastening the cover plate 13 to different openings 110 of every blocking device 11, the space between the cover plate 13 and the carrier surface 100 can be adjusted. By increasing the height h of the space, the wafer holder 1 may accommodate more nitride-based semiconductor wafers with a plurality of protecting layers. By decreasing the height h of the gap, the wafer holder 1 may accommodate less nitride-based semiconductor wafers with the same number of protecting layers. Therefore, the same amount of protecting layers are needed for most of the situation.

In other words, the cover plate 13 is coupled to the blocking devices 11, and the blocking devices 11 are configured to adjust the height h of the cover plate 13. Therefore, the wafer holder 1 is suitable to carry any numbers of nitride-based semiconductor wafers.

In the wafer holder 1, each of the blocking structures 11 has a plurality of connecting structures, and, in each of the blocking structures 11, the connecting structure are disposed on different height.

In this embodiment, the connecting structures of every blocking structure 11 are openings 110. In some other embodiments, the connecting structures of every blocking structure 11 could be other structure that are configured to couple to the cover plate 13.

To be specific, the cover plate 13 of this embodiment has a plurality of connecting structures as well, and the connecting structures of the cover plate 13 are configured to connect the connecting structures of the blocking structures 11. In this embodiment, the number of the connecting structures of the cover plate 13 and the number of the blocking structures 11 are the same, and each of the connecting structures of the cover plate 13 is corresponded to one of the blocking structures 11.

In this embodiment, the connecting structures of the cover plate 13 are holes 133, which will be explained in detail in the following description. Also, the wafer holder 1 comprises the fasteners 12, and the cover plate 13 is coupled to the blocking devices 11 through the fasteners 12.

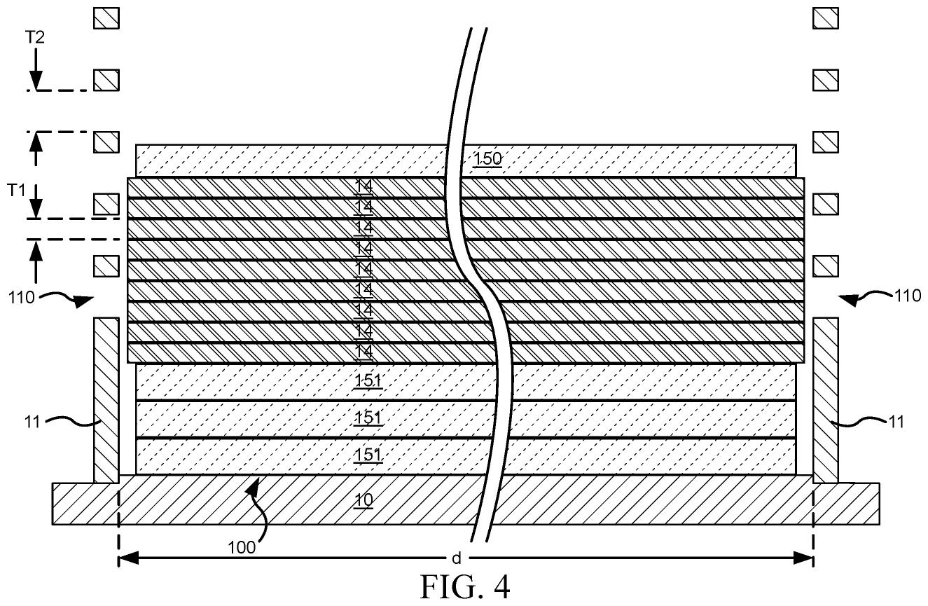

FIGS. 4-6 are sectional views of steps of operating method of the wafer holder 1 according to some embodiments of the present disclosure.

Please refer to FIG. 4. The operating method of the wafer holder 1 disposes a plurality of nitride-based semiconductor wafers 14 on the carrier surface 100 of the carrier plate 10. To be specific, in this embodiment, nine wafers 14 are disposed on the carrier surface 100. However, the number of the wafers 14 are not limited thereto. Also, additional protective layer may be disposed in-between the wafers 14.

The carrier surface 100 is located between the blocking devices 11, and the wafers 14 are disposed between the blocking devices 11 as well. For example, in this embodiment, the diameter d of the carrier surface 100 falls in the range from 204 mm to 205 mm, and the carrier surface 100 is adapted to carry one or more 8 inches nitride-based semiconductor wafers.

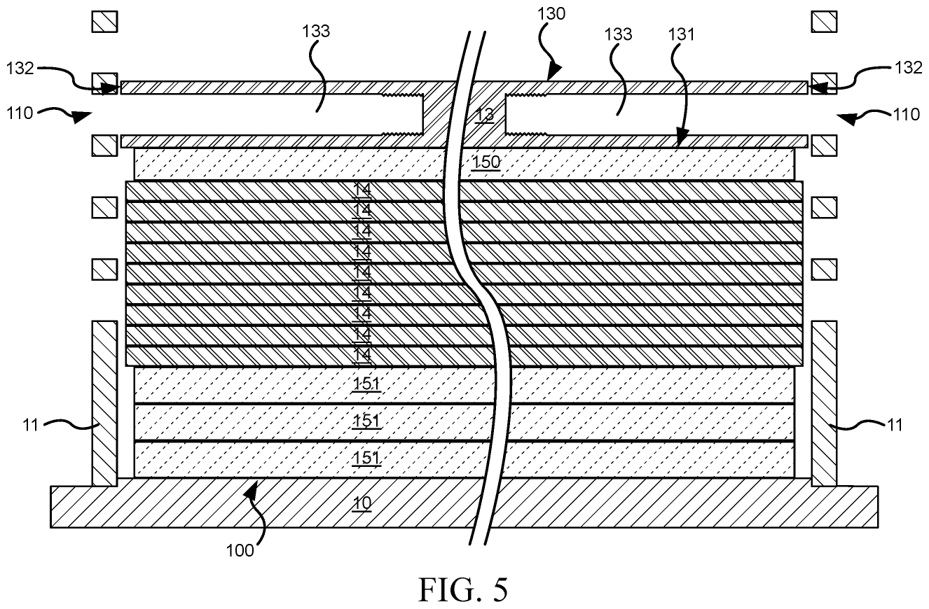

Referring to FIG. 5, the operating method of the wafer holder 1 disposes a cover plate 13 on the wafers 14. To be specific, the cover plate 13 is disposed between the blocking devices 11, and the wafers 14 are located between the carrier surface 100 and the cover plate 13.

In this embodiment, the cover plate 13 has connecting structures that are corresponded to the connecting structures (openings 110) of the blocking devices 11. The connecting structures of the cover plate 13 are configured to align with the openings 110 of the blocking devices 11.

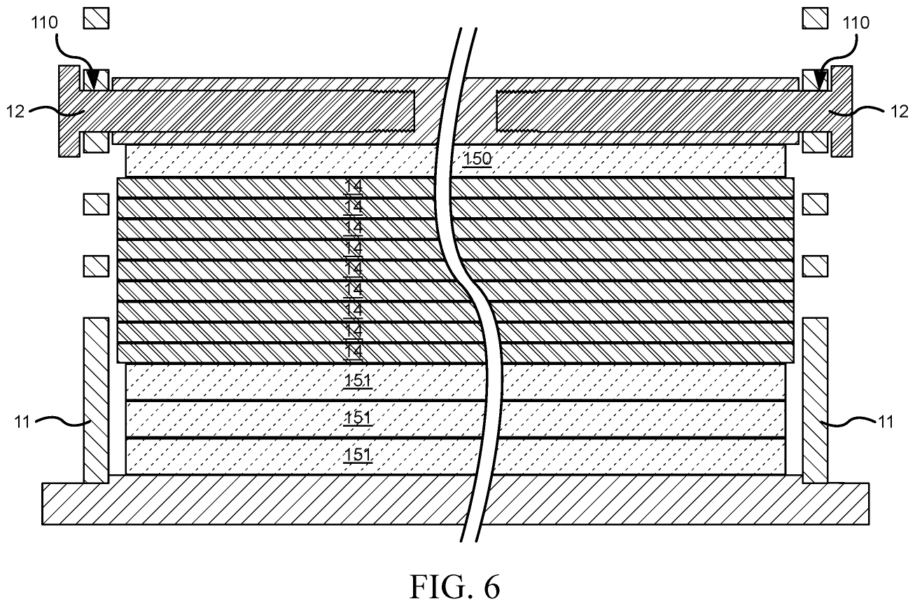

Referring to FIG. 6, the operating method of the wafer holder 1 inserts a plurality of fasteners 12 to the openings 110 of the blocking devices 11 located around the carrier surface 100, and the operating method fastens the cover plate 13 on the blocking devices 11. In other words, the cover plate 13 is fastened on the blocking devices 11 through the fasteners 12.

When the wafers 14 are accommodated in the wafer holder 1, the cover plate 13 covers the entire top surfaces of the wafers 14. Therefore, the wafers 14 can be protected in-between the carrier surface 100 and the cover plate 13.

Referring to FIG. 5, the cover plate 13 of this embodiment has a top surface 130, a bottom surface 131, a side surface 132, and a plurality of holes 133.

In the cover plate 13, the side surface 132 connects the top surface 130 and the bottom surface 131. The holes 133 are formed on the side surface 132, and the holes 133 are the connecting structures of the cover plate 13 that corresponded to the openings 110 of the blocking devices 11.

In the operating method of the wafer holder 1, the step of fastening the cover plate 13 comprises: inserting the fasteners 12 into the holes 133. Each of the hole 133 is configured to be aligned with one of the openings 110, and the fasteners 12 can be inserted into the holes 133 of the cover plate 13 through the openings 110 of the blocking devices 11.

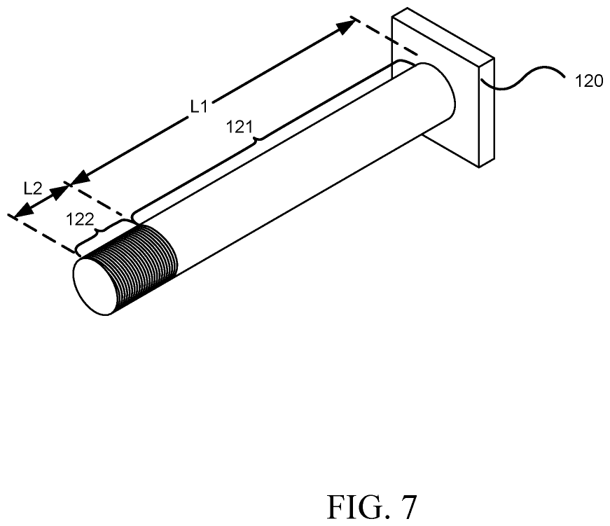

FIG. 7 is a perspective view of the fastener 12 according to some embodiment of the present disclosure. In this embodiment, the fastener 12 is a bolt. The fastener 12 has a thread part 122 and a shank part 121, and a thread length L2 of every fastener 12 (bolt) is shorter than a shank length L1 of the fastener 12 (bolt).

Also, the bolts have a square head 120. Every fastener 12 has a square head 120, and the shank part 121 of the fastener 12 is between the thread part 122 and the square head 120. In other words, the thread part 122 of the fastener 12 is at one end of the fastener 12. User can hold and twist the fastener 12 easily through the square head 120, and properly fasten the cover plate 13 to the blocking devices 11.

In some other embodiment of the present disclosure, shape of the head 120 of the fastener 12 can be circle, triangle, pentagon, hexagon, or any polygon.

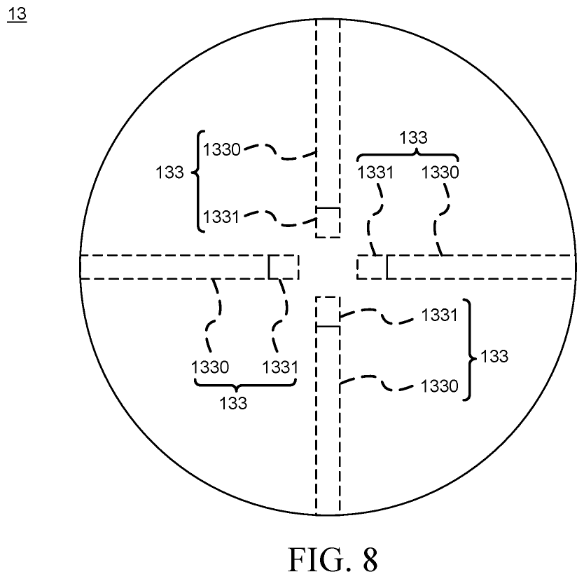

FIG. 8 is a top view of the cover plate 13 according to some embodiments of the present disclosure, and the holes are shown with dashed lines. Referring to FIG. 8, every hole 133 of the cover plate 13 has a smooth area 1330 and a threaded area 1331. The threaded areas 1331 of the holes 133 are located near the center of the cover plate 13. Therefore, the threaded areas 1331 are corresponded to the thread parts 122 of the fasteners 12, and the smooth areas 1330 are corresponded to the shank parts 121 of the fasteners 12, and the fasteners 12 can be fastened in the holes 133. In other words, in the operating method, after the step of inserting the fasteners 12, the method further comprises: fastening the fasteners 12 to the holes 133.

The cover plate 13 of this embodiment is rounded, and the cover plate 13 has a size that is slightly bigger than the size of an 8 inches nitride-based semiconductor wafer. In some other embodiments, the cover plate 13 may have the same size of the 8 inches nitride-based semiconductor wafer. Therefore, the cover plate 13 can properly cover the wafer 14 on the carrier surface 100.

In one aspect, referring to FIG. 1, the carrier surface 100 is rounded, and the blocking devices 11 are evenly separated around the carrier surface 100. In other words, the blocking devices 11 surround the carrier surface 100, and projections of the inner surfaces 112 of the blocking devices 11 are coincide with the edge of the carrier surface 100. When facing towards the carrier surface 100, the blocking devices 11 are located at 12, 3, 6, 9 o'clock positions of the carrier surface 100.

In one aspect, the carrier plate 10 is in the shape of a rounded rectangle, and cover connecting structures can be disposed on the corner areas of the carrier plate 10. To be specific, the carrier plate 10 can have the carrier surface 100 and a peripheral surface 101, and the cover connecting structures can be disposed on the corner areas of the peripheral surface 101. The cover connecting structures are configured to connect to a cover of the wafer holder 1.

Moreover, in the carrier plate 10 of the embodiment, each of the blocking devices 11 is adjacent to one of the sides 102 of the rounded rectangle. Therefore, the corner areas of the carrier plate 10 can provide sufficient space for disposing the connecting structures without blocking the blocking devices 11.

In some other embodiments, the carrier plate 10 is in the shape of a rectangle.

Referring to FIG. 3, the square head 120 of the fastener 12 is bigger than the openings 110 of the blocking devices 11. When a fastener 12 is inserted to an opening 110, the square head 120 of the fastener 12 is adapted to cover the opening 110.

In the wafer holder 1, each of the blocking devices 11 has a curved wall 111, and the openings 110 are formed on the curved wall 111. Therefore, the blocking device 11 can hold the wafers 14 and the cover plate 13 with the curved wall 111 properly, while the openings 110 fasten the cover plate 13.

Referring to FIG. 4, the blocking devices 11 stand at right angles to the carrier surface 100. Therefore, the space between the blocking device 11 can accommodate the wafers 14.

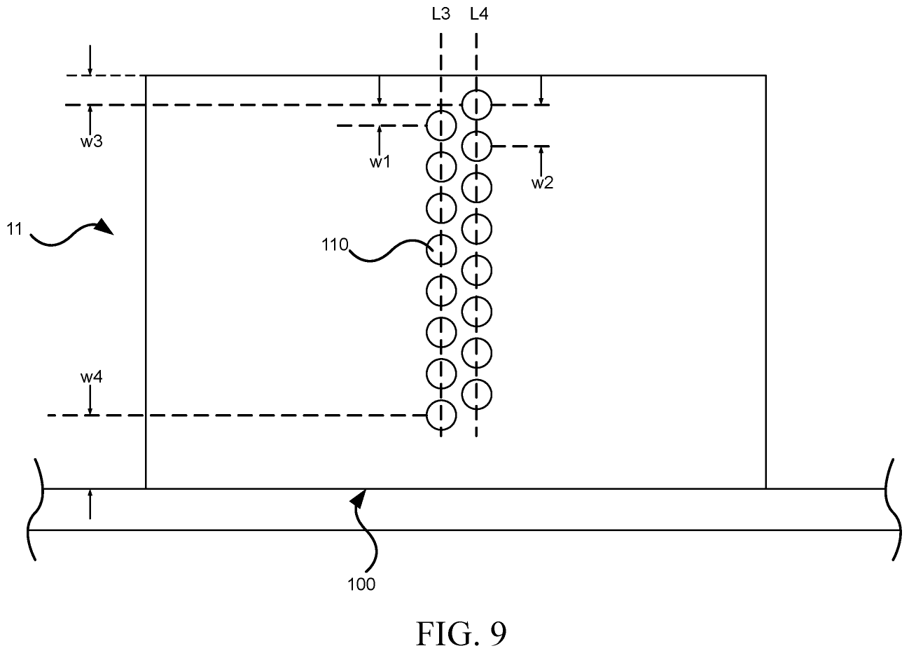

FIG. 9 is a front view of the blocking device 11 according to some embodiment of the present disclosure. Referring to FIG. 9, the openings 110 are arranged along two straight lines L3, L4 on every blocking device 11, and the two straight lines L3, L4 are perpendicular to the carrier surface 100. Therefore, in every blocking device 11, different openings 110 can hold the cover plate 13 in different height with the fastener 12.

In one aspect, the openings 110 of the blocking device 11 are rounded and have the same diameter. Therefore, the fasteners 12 can fit in all the openings 110.

In every blocking device 11, the smallest height difference w1 between two adjacent openings 110 is 1.5 mm, and the smallest height difference w2 between two adjacent openings 110 in straight line L4 is 3 mm. Therefore, by changing the opening 110 that passed through by the fastener 12, the cover plate 13 can adjust its height by 1.5 mm, which is a sufficient thickness for a nitride-based semiconductor wafer 14. In other words, the openings 110 in every blocking device 11 are in different heights, and the smallest difference among the heights is about a thickness of the wafer 14. Moreover, the thickness can fit in the wafer 14 and a Tyvek paper, so as to avoid scratching between the wafers 14.

In one aspect, the thickness w3 between the top of the blocking device 11 and the first opening 110 is about 1.15-0.5X mm, wherein the X is the thickness of the cover plate 13. Therefore, at least one cushion layer can be disposed on the wafer when the wafer holder 1 is filled with wafers 14.

In one aspect, the thickness w4 between the carrier surface 100 and the last opening 110 is about 36.85+0.5X mm, wherein the X is the thickness of the cover plate 13. Therefore, the wafer holder 1 can hold a single wafer 14 properly.

Referring to FIG. 4, during the operation method of the wafer holder 1, one or more base cushion 151 can be disposed on the carrier surface 100 before the wafers 14 are disposed. A base cushion 151 is disposed on the carrier surface 100, and the base cushion 151 can be made of foam. The thickness of the base cushion 151 can be 15 mm. Therefore, when the wafers 14 are disposed on the carrier surface 100, the base cushion 151 may carry and protect the wafers 14.

To be specific, in this embodiment, three base cushions 151 are disposed on the carrier surface 100. However, the present disclosure is not limited to the number of the base cushions 151. In some embodiments, there may be only one base cushion 151 disposed on the carrier surface 100. Moreover, a Tyvek paper may be disposed on the base cushion 151.

In one aspect, a diameter T2 of every opening 110 is twice a thickness T1 of the wafer 14. Therefore, the fasteners 12 can be thick enough to hold the cover plate 13 and protect the wafers 14.

In one aspect, during the operation method of the wafer holder 1, at least one cushion layer 150 may be disposed on the wafers 14 after disposing the wafers 14.

In this embodiment, one cushion layer 150 is disposed on the wafers 14, and the cushion layer 150 can be made of foam. Moreover, a Tyvek paper may be disposed on the wafers 14 before the cushion layer 150 is disposed. However, the present disclosure is not limited to the number of the cushion layer 150.

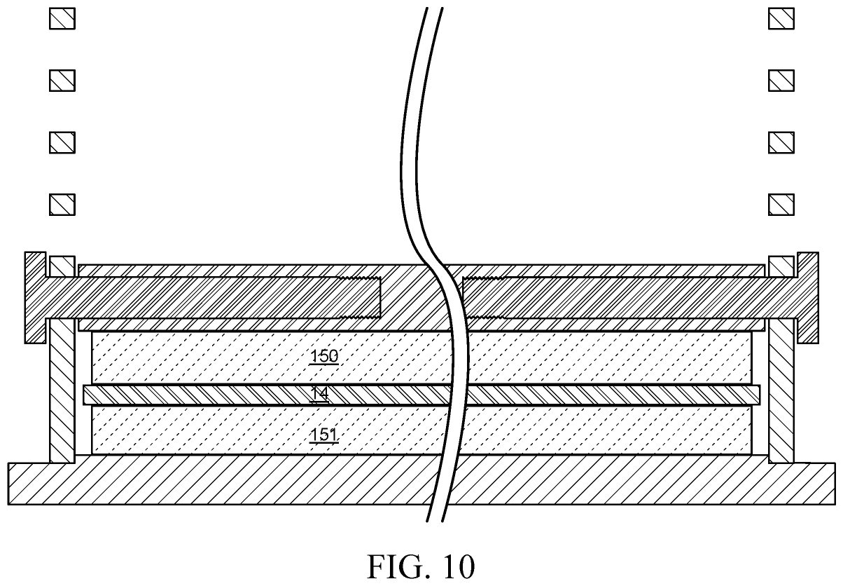

The number of the base cushions 151 are different from the cushion layer 150 on the wafers 14. However, the present disclosure is not limited thereto. FIG. 10 is a sectional view of a wafer holder according to some embodiment of the present disclosure. Referring to FIG. 10, in this wafer holder, only one base cushion 151 is disposed below the wafer 14, and only one cushion layer 150 is disposed on the wafer 14. Moreover, a Tyvek paper may be disposed between the wafer 14 and the base cushion 151, and another Tyvek paper may be disposed between the wafer 14 and the cushion layer 150.

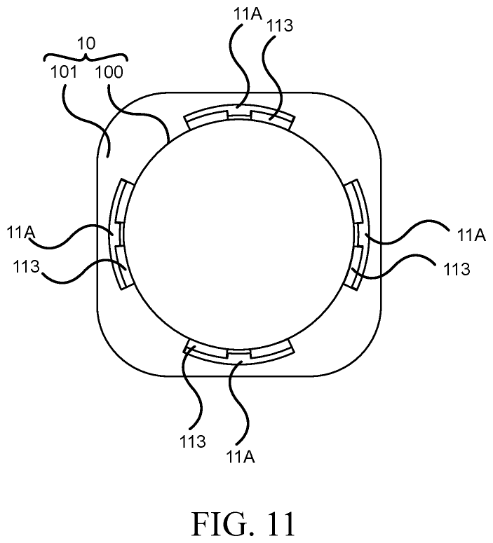

FIG. 11 is a top view of a carrier plate according to some other embodiments of the present disclosure. In this embodiment, each of the blocking devices 11A has a side cushion 113. The carrier plate has a carrier surface 100 and a peripheral surface 101 surrounding the carrier surface 100, and the side cushions 113 face towards the carrier surface 100.

When one or more wafers are disposed on the carrier surface 100, the side cushions 133 of the blocking devices 11A can surround and protect the wafers.

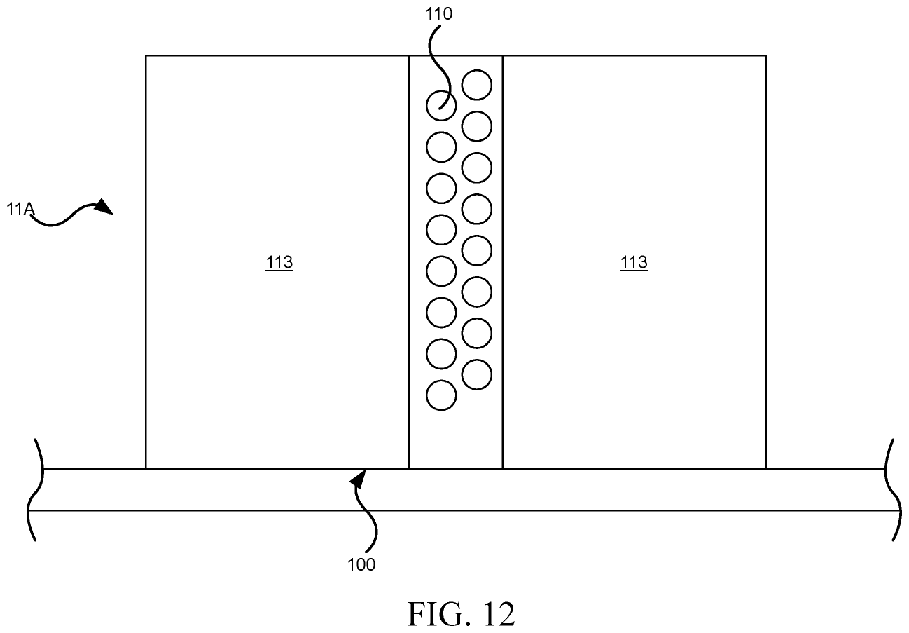

FIG. 12 is a front view of a blocking device 11A according to some embodiments of the present disclosure. Referring to FIG. 12, in every blocking device 11A, two side cushions 133 are disposed beside the openings 110, and the side cushions 133 are adapted to touch and hold one or more wafers disposed on the carrier surface 100, while the openings 110 can fasten a cover plate 13 with a plurality of fasteners.

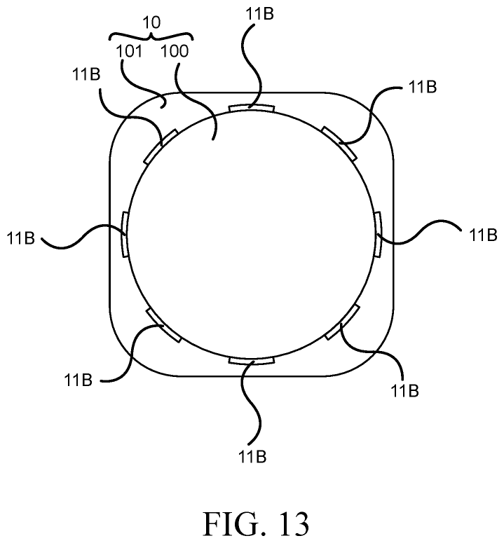

Referring to FIG. 1, in this embodiment, four blocking devices 11 are disposed on the carrier plate 10. However, the present disclosure is not limited thereto. FIG. 13 is a top view of a carrier plate according to some other embodiment of the present disclosure. In this embodiment, eight blocking devices 11B with narrow width are disposed on a carrier surface 100 of the carrier plate 10, and a peripheral surface 101 surrounds the carrier surface 100.

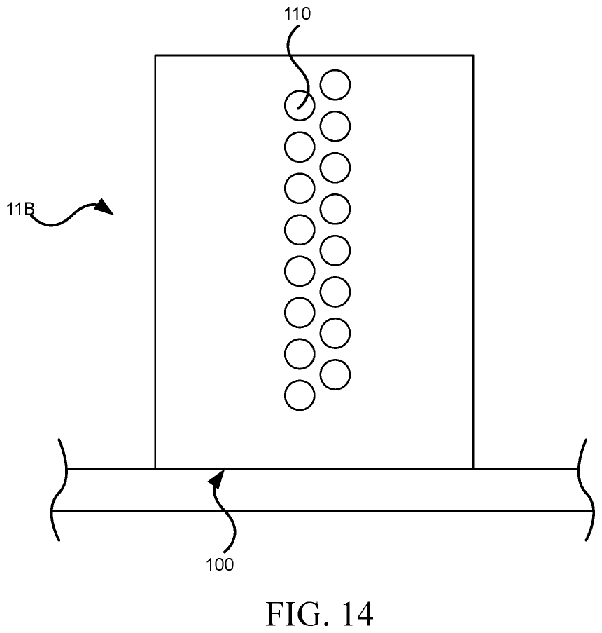

FIG. 14 is a front view of a blocking device 11B according to some embodiments of the present disclosure. Referring to FIG. 14, in every blocking device 11B, a plurality of openings 110 may be formed, and the arrangement of the openings 110 may be similar to the arrangement of the openings 110 of blocking devices 11, while the width of the blocking device 11B is narrower than blocking device 11. Therefore, a cover plate 13 may be fastened above the carrier surface 100 with eight fasteners, and provide a more stable protection to the wafers on the carrier surface 100.

The embodiments were chosen and described in order to best explain the principles of the invention and its practical application, thereby enabling others skilled in the art to understand the invention for various embodiments and with various modifications that are suited to the particular use contemplated.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to +10% of that numerical value, such as less than or equal to +5%, less than or equal to +4%, less than or equal to +3%, less than or equal to +2%, less than or equal to #1%, less than or equal to +0.5%, less than or equal to +0.1%, or less than or equal to +0.05%. The term “substantially coplanar” can refer to two surfaces within micrometers of lying along a same plane, such as within 40 μm, within 30 μm, within 20 μm, within 10 μm, or within 1 μm of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. Further, it is understood that actual devices and layers may deviate from the rectangular layer depictions of the FIGS. and may include angles surfaces or edges, rounded corners, etc. due to manufacturing processes such as conformal deposition, etching, etc. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. A wafer holder, comprising:
a carrier plate having a carrier surface;
a plurality of blocking devices disposed on the carrier plate;
a plurality of fasteners; and
a cover plate located above the carrier surface,
wherein the blocking devices are disposed around the carrier surface, and each of the blocking devices has a plurality of openings, and the fasteners pass through the openings, and the cover plate is fastened on the blocking devices through the fasteners.

2. The wafer holder of claim 1, wherein the carrier surface is rounded, and the blocking devices are evenly separated around the carrier surface.

3. The wafer holder of claim 1, wherein the blocking devices stand at right angles to the carrier surface, and the openings are arranged along two straight lines on every blocking device, and the two straight lines are perpendicular to the carrier surface.

4. The wafer holder of claim 1, wherein the openings of the blocking devices are rounded and have the same diameter.

5. The wafer holder of claim 1, wherein the wafer holder is adapted to accommodate at least one wafer, and a diameter of every opening is twice a thickness of the wafer.

6. The wafer holder of claim 1, wherein the wafer holder is adapted to accommodate at least one wafer, and the openings in every blocking device are in different heights, and the smallest difference among the heights is about a thickness of the wafer.

7. The wafer holder of claim 1, wherein the carrier plate is in the shape of a rectangle or a rounded rectangle.

8. The wafer holder of claim 7, wherein each of the blocking devices is adjacent to one of the sides of the rectangle or rounded rectangle.

9. The wafer holder of claim 1, wherein the fasteners are bolts.

10. The wafer holder of claim 9, wherein a thread length of every bolt is shorter than a shank length of the bolt.

11. The wafer holder of claim 9, wherein the bolts have square head.

12. The wafer holder of claim 1, wherein each of the blocking devices has a curved wall, and the openings are formed on the curved wall.

13. The wafer holder of claim 12, wherein each of the blocking devices has a side cushion, and the side cushions face towards the carrier surface.

14. The wafer holder of claim 1, wherein the cover plate has a top surface, a bottom surface, a side surface, and a plurality of holes, and the side surface connects the top surface and the bottom surface, and the holes are formed on the side surface, and the fasteners are inserted into the holes.

15. The wafer holder of claim 1, wherein the cover plate is rounded.

16. A operating method of a wafer holder, comprising:
disposing at least one wafer on a carrier surface of a carrier plate;
disposing a cover plate on the wafer;
inserting a plurality of fasteners to a plurality of openings of a plurality of blocking devices located around the carrier surface; and
fastening the cover plate on the blocking devices,
wherein the wafer holder comprises the carrier plate, the blocking devices, the fasteners, and the fasteners pass through the openings, and the cover plate is fastened on the blocking devices through the fasteners.

17. The operating method of claim 16, wherein, after disposing the wafer, the method further comprises:
disposing at least one cushion layer on the wafer.

18. The operating method of claim 16, wherein the cover plate has a top surface, a bottom surface, a side surface, and a plurality of holes, and the side surface connects the top surface and the bottom surface, and the holes are formed on the side surface, and the step of fastening the cover plate comprises:
inserting the fasteners into the holes.

19. The operating method of claim 18, wherein the fastener are bolts, and, after the step of inserting the fasteners, the method further comprises:
fastening the fasteners to the holes.

20. The operating method of claim 16, wherein, before disposing the wafer, the method further comprises:
disposing a base cushion on the carrier surface.

21-25. (canceled)
